(19) United States
(12) Patent Application Publication
(10) Pub. No.: US 2009/0308453 A1
(43) Pub. Date: Dec. 17, 2009

(54) HETEROJUNCTION WITH INTRINSICALLY AMORPHOUS INTERFACE

(75) Inventors: Pere Roca I Cabarrocas, Villebon Sur Yvette (FR); Jeröme Damon-Lacoste, Bourg La Reine (FR)

Correspondence Address: PAULEY PETERSEN & ERICKSON, 2800 WEST HIGGINS ROAD, SUITE 365, HOFFMAN ESTATES, IL, 60169, US

(73) Assignees: CENTRE NATIONAL DE LA RECHERCHE SCIENTIFIQUE (CNRS), Paris (FR); ECOLE POLYTECHNIQUE, Palaiseau (FR)

(21) Appl. No.: 12/520,309

(22) PCT Filed: Dec. 20, 2007
(86) PCT No.: PCT/EP2007/064373

§ 371 Date: Jun. 19, 2009

(30) Foreign Application Priority Data
Dec. 20, 2006 (FR) 0655711

(51) Int. Cl. H01L 31/0264; H01L 21/20

(52) U.S. Cl. 136/258; 438/96; 257/E21.09

(57) ABSTRACT

The invention relates to a structure (100) for photovoltaic applications including: a first layer (10) of a crystalline semiconductor material having a front face (1) for receiving and/or emitting photons and a back face (2); a back contact (40) of a conductive material provided on the side of the back face (2); characterised in that it further comprises a second layer (50) of hydrogenated amorphous silicon-germanium (a-SiGe:H) between the back face (2) of the first layer (10) and the back contact (40). The invention also relates to a method for realising said structure (100).

The invention relates to the field of photovoltaic cells, and more particularly to that of photovoltaic cells using heterojunctions.

This invention may in particular relate to cells comprising:
a central layer in-doped crystalline silicon (c-Si) for receiving and/or emitting photons on the front face;
optionally, a layer in-doped amorphous silicon (a-Si) located on the front face; and
a rear contact layer, in an electrically conducting material, located on the rear face of the central layer.

The contact layer may for example be in a metal material or in a transparent conducting oxide—such as ITO (Indium Tin Oxide).

This type of structure comprises a heterojunction consisting of the central layer and of the rear contact layer.

Such a normally or strongly doped heterojunction suffers from poor interface quality related to poor passivation of the c-Si layer, as well as from a too large potential barrier at the interface, with the consequence of poor collection of the carriers.

A detrimental effect is a significant loss of the signal between the central layer and the rear contact layer, which limits the yield of the cell.

In order to reduce this problem, it is known how to interpose a layer in hydrogenated amorphous silicon (a-Si:H) between the c-Si and the rear contact layer.

However, the improvement of the interface quality remains insufficient.

Problems of diffusion of metal elements from the front and rear contact layer of the cell may further occur during the formation of the a-Si:H layer.

A goal of the invention is to provide new solutions to the problem of the quality of the interface between the c-Si and the rear contact layer, on the rear face of the c-Si layer.

Another goal is to increase the feasibility of the rear face.

Another goal of the invention is to increase the yield of photovoltaic cells with heterojunctions, to lower the costs, and/or increase the (conversion yield/photovoltaic module cost) ratio.

Another goal of the invention is to limit the temperature for making the cell.

In order to achieve these goals, the invention according to a first aspect proposes a structure for photovoltaic applications, comprising:
a first layer in a crystalline semiconducting material having a front face for receiving and/or emitting photons and a rear face;
a rear contact in a conducting material located on the side of the rear face;
   characterized in that it further comprises:
a second layer in hydrogenated amorphous silicon-germanium (a-SiGe:H) between the rear face of the first layer and the rear contact.

Other optional features of this structure according to the invention are the following:
the second layer is doped or intrinsic;
said crystalline semiconducting material is mono-, poly- or multi-crystalline silicon (Si) and optionally Si is p-doped and a-SiGe:H is p-doped, or Si is n-doped and a-SiGe:H is n-doped;
the second layer further comprises carbon;
the rear contact layer is in a metal material or in a transparent conducting oxide such as ITO;
the Ge concentration in the second layer gradually varies in the thickness of the later; the Ge concentration in the second layer may gradually vary in the thickness of the latter so as to be higher on the side of the rear contact layer and lower on the side of the first layer;
the structure further comprises a third layer in a amorphous or polymorphous semiconducting material, optionally doped, on the front face of the first layer; the third layer is optionally in hydrogenated amorphous Si or in hydrogenated amorphous SiGe; the third layer is optionally n-doped if the first layer is p-doped, or the third layer is p-doped if the first layer is n-doped; the structure may further comprise a front contact layer in an electrically conducting transparent material on the third layer, the conducting material may be a transparent conducting oxide such as ITO;
the second layer has a forbidden band between about 1.2 and 1.7 eV, and more particularly of the order 1.5 eV.

According to a second aspect, the invention proposes a method for making a structure for photovoltaic applications, comprising the following steps of:

(a) providing a first layer in a crystalline semiconducting material having a front face for receiving and/or emitting photons and a rear face;

(b) forming a second layer by depositing hydrogenated amorphous silicon-germanium (a-SiGe:H) on the rear face of the first layer;

(c) forming a rear contact layer in an electrically conducting material on the second layer.

Other optional features of this method according to the invention are the following:
step (a) and/or (b) further comprises an implantation of dopant elements;
step (b) is applied at a temperature lower than or similar to 250° C.;
step (b) is applied so that the Ge concentration in the second layer gradually varies in the thickness of the latter; the Ge concentration in the second layer may in particular gradually increase from the first layer;
the method further comprises a selection of the hydrogen concentration in the second layer in order to adjust the valence and conduction bands, so as to obtain discontinuities of valence bands and of conduction bands respectively, determined at the interface with the first layer; the second layer may be n-doped, the valence band discontinuity is sufficiently strong in order to produce a potential barrier capable of repelling holes from the interface and thereby preventing recombination at the interface, and the conduction band discontinuity is sufficient low in order to minimize the blocking of the electrons at the interface; alternatively, the second layer may be p-doped, the valence band discontinuity is sufficiently low for minimizing blocking of the holes at the interface, and the conduction band discontinuity is sufficiently strong for repelling the electrons from the interface and thereby preventing a recombination at the interface; the method further comprises a selection of the germanium concentration in the second layer so that the forbidden band of the material of the rear portion of the second layer has a determined width;
the method further comprises the formation of a third layer in an optionally doped, hydrogenated amorphous material on the front face of the first layer, the third layer being in an amorphous or polymorphous semiconducting material; optionally, the method comprises the formation of an electric contact layer in an electrically conducting material transparent to photons, on the third layer.

Other features, objects and advantages of this invention will be better understood upon reading the following description which is non-limiting, illustrated by the following single FIGURE:

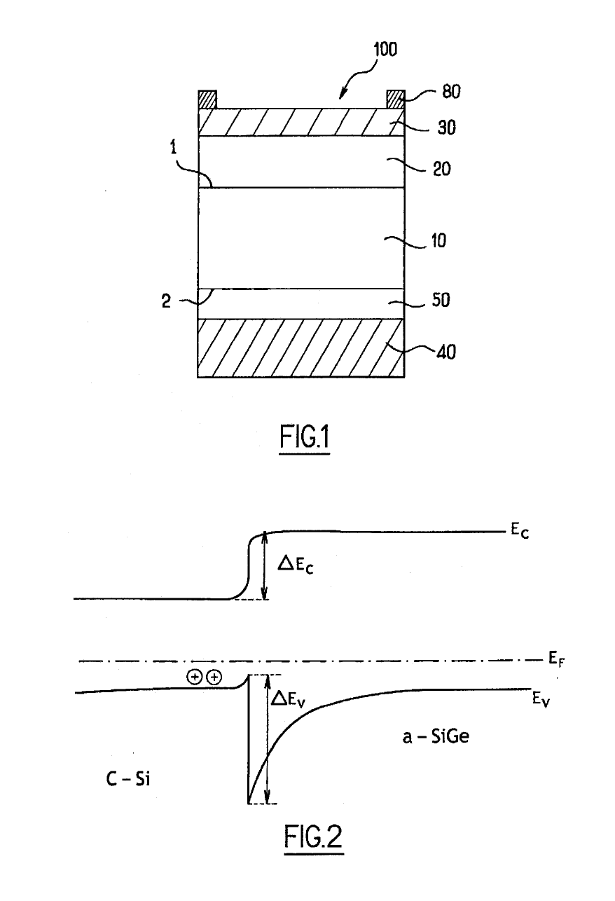

FIG. 1 illustrates a schematic transverse sectional view of a structure with heterojunctions for a photovoltaic application according to the invention.

FIG. 2 illustrates an example of a band diagram of the rear face of a p-type c-Si/p-type a-SiGe heterojunction.

A heterojunction structure 100, such as for example a photoelectric cell, includes an active layer or a doped crystalline (for example monocrystalline, polycrystalline or multicrystalline) substrate 10 and a doped amorphous material layer 20 having a difference in forbidden band values and therefore band discontinuities between each other.

Preferably, either the active layer 10 is n-doped and the amorphous layer 20 is p-doped, or the active layer 10 is p-doped and the amorphous layer 20 is n-doped.

For example, silicon and/or SiGe may be selected for forming both of these layers 10 and 20.

This amorphous/crystalline heterojunction is produced in order to obtain a determined voltage at the front face.

The active layer 10 may have a thickness of several micrometers or even several hundred micrometers.

Its resistivity may be less than 20, 10 ohms or more particularly around 5 ohms or less.

The active layer 10 includes a front face 1 and a rear face 2.

The front face 1 is intended for receiving the photons (and/or for emitting the latter).

The rear face 2 is intended to be connected to a rear electric contact.

The doped amorphous layer 20 is located on the side of the front face 1.

A front contact layer 30 in a metal material or in a transparent conducting oxide such as ITO (Indium Tin Oxide) may be provided on the amorphous layer 20. Optionally, screen-printed metal patterns 80 may be found on this front contact layer 30.

A rear contact layer 40 in a metal material or in a transparent conducting oxide such as ITO, is moreover provided on the side of the rear face 2 of the active layer 10;

According to the invention, an a-SiGe:H transition layer 50 is interposed between the active layer 10 and this rear contact layer 40.

Alternatively, this silicon-germanium layer may be in a polymorphous material, therefore of the pmSiGe:H type.

In order to make such a transition layer 50, deposition for example by PECVD, of the amorphous or polymorphous material is then carried out on the rear face 2 of the active layer 10. More details on one or more deposition techniques may for example be found in “Hydrogenated amorphous silicon deposition processes” of Werner Luft and Y. Simon Tsuo (Copyright 1993 of Marcel Dekker Inc. ISBN 0-8247-9146-0).

With such a transition layer 50 according to the invention, the surface of the crystalline silicon may be very well passivated, the amorphous or polymorphous silicon-germanium having suitable properties for reducing the presence of interface defects with for example an active c-Si layer 10.

Another advantage of such a transition layer 50 is that the amorphous silicon-germanium alloys on the rear face of cells with heterojunctions have a smaller forbidden band width (“gap”) then amorphous silicon and therefore closer to the c-Si forbidden band of the active layer 10. One will thus have typically, in the case when the active layer 10 is in c-Si, an a-SiGe:H transition layer 50 with a potential barrier less than that of a-Si:H, for equivalent deposits and thicknesses.

With an a-SiGe:H transition layer 50, it is therefore also possible:
to well or even better passivate the rear face 2 of the active layer 10,
while further approaching the electric properties of the active layer 10, thereby facilitating the transport of the carriers from the active layer 10 to the rear contact layer 40,
   than with an a-Si:H transition layer 50.

With an a-SiGe:H transition layer 50, it is therefore possible to improve the contact on the rear face made for extracting the carriers from the structure 100.

The structure or cell 100 therefore gains in yield and accuracy.

Another benefit of the invention lies in the possibility of easily varying the gap of the transition layer 50.

Indeed, the transition layer 50 comprises three elements (Si, Ge and H), the respective concentrations of which determine the gap, as well as the profile of the valence and conduction bands.

In particular, an increase in the germanium content of the a-SiGe:H layers reduces the value of the gap.

Now, it may be very useful to be able to thereby accurately control this gap.

It is thus possible to obtain median values between the electric properties of the active layer 10 and those of the rear contact layer 40.

Optionally, it will be possible to gradually vary the Ge concentration in the thickness of the transition layer 50. This change in concentration may be continuous by continuously varying the dosage of the Ge precursors relatively to the precursors of Si gradually during the deposition, or stepwise by successively depositing layers which have Ge concentrations which are constant in each of them but which vary from one layer to another. Thus, under certain conditions, it may be advantageous if the Ge concentration in the transition layer 50 varies so as to be higher on the side of the rear contact layer 40 and lower on the side of the active layer 10, in order to gradually reduce the gap of the transition layer 50 to between the gap of the active layer 10 and that of the rear contact layer 40.

Further, the change in the hydrogen content of the material may modify the distribution of the valence and conduction band discontinuities at the interface, without however having that the value of the gap be necessarily changed.

With reference to FIG. 2, illustrating the valence band discontinuities ΔEᵥ and the conduction band discontinuities ΔE_{c} existing at the interface between the c-Si on the one hand (left portion of the band diagram) and a-SiGe:H on the other hand (right portion), it may be realized that it is actually possible to vary the value of ΔEᵥ and the value of ΔE_{c} without however having to change the gap difference between both materials (this difference being equal to the sum of ΔEᵥ and of ΔE_{c}).

In particular, an increase in the hydrogen concentration in the transition layer 50 may allow an increase of ΔEᵥ while decreasing ΔE_{c} and, conversely, a reduction in the hydrogen concentration in the transition layer 50 may allow a decrease of ΔEᵥ while increasing ΔE_{c}.

A preliminary selection of the hydrogen concentration in the transition layer 50 is therefore advantageously made suitably according to the invention, so as to adjust the valence and conduction bands of the transition layer 50 in order to respectively obtain determined discontinuities of valence and conduction bands at the interface with the active layer 10.

In particular, a hydrogen concentration may be selected for:
if the transition layer 50 is n-doped, obtaining a sufficiently large ΔEᵥ for producing a potential barrier capable of sufficiently repelling the holes from the interface in order to prevent them from recombining there and a sufficiently small ΔEᵥ for limiting the blocking of the electrons at the interface; or
if the transition layer 50 is p-doped, obtaining a sufficiently small ΔEᵥ for minimizing the potential barrier at the interface and thereby facilitating the displacement of the holes towards the rear contact 40, and a sufficiently large ΔE_{c} for producing a potential barrier capable of sufficiently repelling the electrons from the interface in order to prevent them from recombining there.

More details concerning the influence of the hydrogen rate on the distribution of band discontinuities may for example be found in the publication of Chris G. Van de Walle entitled “Band discontinuities at heterojunctions between crystalline and amorphous silicon” (Journal of Vacuum Science & Technology B, Vol. 13, p. 1635-1638 (1995)).

Therefore according to the invention, it is possible to optimize the electric interface property at the rear face of the cell 100 by acting on the parameters for depositing the transition layer 50, and in particular by selecting the respective particular Ge and H compositions.

The invention therefore provides an additional degree of freedom in the engineering of bands of the rear faces of cells with heterojunctions.

Further, by varying the germanium and/or hydrogen content according to the invention, it is possible to change the nature and the properties of the amorphous material while not changing the temperature of the deposition.

This adjustment of the deposition parameters is therefore not at all restrictive from the point of view of time (temperature rise time), energy and handling.

With the invention, it is for example possible to obtain small forbidden band widths for the amorphous semiconductor (between 1.1 and 1.7 eV, and more particularly of the order of 1.5 eV) and/or a property of the amorphous material deposited on the rear face without increasing the temperature too much (of the order of 250° C.).

Another benefit of the invention is that, in order to obtain a same predetermined gap value, the deposition temperature for an a-SiGe:H layer (which is typically similar to or less than 250° C.) is below the temperature for depositing an a-Si:H layer.

As an illustration, the table gives correspondences between gaps and temperatures, for different Ge concentrations:

| Gap (eV) | a-Si: H | a-Si_{0.95}Ge_{_{0.05}}: H | a-Si_{0.9}Ge_{_{0.1}}: H |
|---|---|---|---|
| 1.39 | — | — | 200° C. |
| 1.48 | 300° C. | — | — |
| 1.51 | — | 200° C. | — |
| 1.58 | — | 150° C. | — |
| 1.60 | 250° C. | — | — |
| 1.67 | 200° C. | — | — |
| 1.74 | 150° C. | — | — |

Therefore, the formation of such an a-SiGe:H layer is more economical in time and in energy than the formation of an a-Si:H layer.

The heating budget to be anticipated is therefore simpler to handle and less costly.

Further, by this temperature reduction relatively to a-Si:H, it is possible to reduce the risks of diffusion into the semiconductors of the layers 10, 20, 50 of conducting elements (for example metal elements) from the contact layers 30-40, which would clearly be detrimental to the operation of the cell 100.

Optionally, the transition layer 50 is further p-doped or n-doped.

The structure 100 may for example comprise an active layer 10 in p type crystalline silicon, an a-Si:H layer 20 of type n on the front face 1 and an a-SiGe:H layer 50 of type p on the rear face 2. The dopant element(s) may be selected from: P, B, As, Zn, Al.

Alternatively, the structure 100 may for example comprise an active layer 10 in crystalline silicon of type n, an a-Si:H layer 20 of type p on the front face 1 and an a-SiGe:H layer 50 of type n on the rear face 2. The dopant element(s) may be selected from: P, B, As, Zn, Al.

By producing on the rear face 2 an a-SiGe:H layer 50 with doping of the same type as that of the active c-Si layer 10, it is possible to further reduce recombinations of carriers before the rear contact layer 40.

The other layers 40, 20, 50 of the structure 100 are deposited by techniques known per se, such as vapor phase deposition or other techniques.

A field of application of this invention using amorphous silicon-germanium relates to the power sector, and in particular: the cells 100 may be used for converting solar energy into electrical energy.

As explained earlier, the cells 100 according to the invention are made at a lesser cost while having a greater yield.

1-24. (canceled)

25. A structure for photovoltaic applications, comprising:
a first layer made of a crystalline semiconducting material having a front face for receiving and/or emitting photons, and a rear face;
a rear contact layer made of a conducting material located on the side of the rear face; and
a second single layer made of hydrogenated amorphous silicon-germanium (a-SiGe:H) located between the rear face of the first layer and the rear contact layer.

26. The structure of claim 25, wherein the hydrogenated amorphous silicon-germanium is selected among doped hydrogenated amorphous silicon-germanium (a-SiGe:H) and intrinsic hydrogenated amorphous silicon-germanium (a-SiGe:H).

27. The structure of claim 25, wherein said crystalline semiconducting material is selected in the group comprising mono-, poly- and multi-crystalline silicon (Si).

28. The structure of claim 27, wherein said mono-, poly- or multi-crystalline silicon (Si) is p-doped and the hydrogenated amorphous silicon-germanium (a-SiGe:H) is p-doped.

29. The structure of claim 27, wherein said mono-, poly- or multi-crystalline silicon (Si) is n-doped and the hydrogenated amorphous silicon-germanium (a-SiGe:H) is n-doped.

30. The structure of claim 25, wherein said second layer further comprises carbon.

31. The structure of claim 25, wherein said rear contact layer is made of a material selected among metals and transparent conductive oxides.

32. The structure of claim 25, wherein the Ge concentration in the second layer gradually varies in the thickness direction thereof.

33. The structure of claims, 29, 30 and 31 taken in combination, wherein the Ge concentration in the second layer gradually varies in the thickness direction thereof so as to be higher at the side of the rear contact layer and lower at the side of the first layer.

34. The structure of claim 25, further comprising a third layer made of an amorphous or polymorphous, optionally doped semiconducting material and located on the front face of said first layer.

35. The structure of claim 34, wherein said third layer is made of a material selected from the group comprising hydrogenated amorphous Si and hydrogenated amorphous SiGe.

36. The structure of claims 28 and 34 taken in combination, wherein said third layer is n-doped.

37. The structure of claims 29 and 34 taken in combination, wherein said third layer is p-doped.

38. The structure of claim 25, further comprising a front contact layer made of an electrically conductive transparent material and located on said third layer.

39. The structure of claim 38, wherein said front contact layer is made of a transparent conducting oxide such as ITO.

40. The structure of claim 25, wherein said second layer has a forbidden band between about 1.2 and 1.7 eV.

41. A method for manufacturing a structure for photovoltaic applications, comprising the steps of:
(a) providing a first layer made of a crystalline semiconducting material, having a front face for receiving and/or emitting photons and a rear face;
(b) forming a second layer by depositing hydrogenated amorphous silicon-germanium (a-SiGe:H) on the rear face of said first layer; and
(c) forming a rear contact layer made of an electrically conductive material on said second layer.

42. The method of claim 41, wherein at least one of step (a) and step (b) is performed at a temperature below or substantially equal to 250° C.

43. The method of claim 41, wherein step (b) is performed in such manner that the Ge concentration in the second layer gradually varies in the thickness direction thereof.

44. The method of claim 43, wherein the Ge concentration in the second layer gradually increases starting from the first layer.

45. The method of claim 41, wherein step (b) comprises selecting the hydrogen concentration in said second layer for adjusting the valence and conduction bands so as to respectively obtain determined discontinuities of valence bands and conduction bands at the interface with said first layer.

46. The method of claim 45, wherein:
the second layer is n-doped, the discontinuity of the valence bands being sufficiently strong to produce a potential barrier capable of repelling holes from the interface, thereby preventing recombination at the interface, and the discontinuity of the conduction bands being sufficiently weak to minimize the blocking of electrons at the interface;
the second layer is p-doped, the discontinuity of the valence bands being sufficiently weak to minimize the blocking of holes at the interface, and the discontinuity of the conduction bands being sufficiently strong to repel the electrons from the interface, thereby preventing recombination at the interface.

47. The method of claim 41, wherein step (b) comprises selecting the germanium concentration in said second layer so that the forbidden band of the material forming the rear portion of the second layer has a determined width.

48. The method of claim 41, further comprising a step of forming a third layer made of an optionally doped, hydrogenated amorphous or polymorphous semiconducting material at the front face of said first layer.

49. The method of claim 48, further comprising a step of forming on said third layer an electric contact layer made of an electrically conductive material, which is transparent to photons.
